(19) United States
(12) Patent Application Publication
(10) Pub. No.: US 2012/0167938 A1
(43) Pub. Date: Jul. 5, 2012

(54) SOLAR CELL, SOLAR CELL SYSTEM, AND METHOD FOR MAKING THE SAME

(75) Inventors: SHOU-SHAN FAN, Beijing (CN); YUAN-HAO JIN, Beijing (CN); QUN-QING LI, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/113,203

(22) Filed: May 23, 2011

(30) Foreign Application Priority Data
Dec. 29, 2010 (CN) 201010612753.X

(51) Int. Cl. H01L 31/042; H01L 31/0352; H01L 31/18

(52) U.S. Cl. 136/244; 438/68; 136/255; 257/E31.011

(57) ABSTRACT

A solar cell includes a first electrode layer, a P-type silicon layer, an N-type silicon layer, and a second electrode layer. The first electrode layer, the P-type silicon layer, the N-type silicon layer, and the second electrode layer are arranged in series side by side along a straight line and in contact with each other, thereby cooperatively forming a planar structure. The planar structure has a photoreceptive surface substantially parallel to the straight line and directly receives an incident light. A P-N junction is formed near an interface between the P-type silicon layer and the N-type silicon layer.

### CROSS-REFERENCE TO RELATED APPLICATIONS

This application claims all benefits accruing under 35 U.S.C. §119 from China Patent Application No. 201010612753.X, filed on Dec. 29, 2010, in the China Intellectual Property Office, the contents of which are hereby incorporated by reference.

### BACKGROUND

1. Technical Field

The present disclosure relates to a solar cell, a solar cell system, and a method for making the same.

2. Description of Related Art

An operating principle of a solar cell is photoelectric effect of a semiconducting material. The solar cells can be roughly classified into silicon-based solar cells, gallium arsenide solar cells, and organic thin film solar cells.

A silicon-based solar cell commonly includes a rear electrode, a P-type silicon layer, an N-type silicon layer, and a front electrode. The P-type silicon layer can be made of polycrystalline silicon or monocrystalline silicon and has a first surface and a flat second surface opposite to the first surface. The rear electrode is disposed on and in ohmic contact with the first surface of the P-type silicon layer. The N-type silicon layer is formed on the second surface of the P-type silicon layer and serves as a photoelectric conversion element. The N-type silicon layer has a flat surface. The front electrode is disposed on the flat surface of the N-type silicon layer. The P-type silicon layer and the N-type silicon layer cooperatively form a P-N junction near an interface of the P-type silicon layer and the N-type silicon layer. In use, light directly irradiates the front electrode, and reaches the P-N junction through the front electrode and the N-type silicon layer. Consequently, a plurality of electron-hole pairs (carriers) can be generated in the P-N junction due to photon excitation. Electrons and holes in the electron-hole pairs can be separated from each other and separately move toward the rear electrode and the front electrode under an electrostatic potential. If a load is connected between the front electrode and the rear electrode, a current can flow through the load.

However, a light absorbing efficiency of the P-N junction of the above solar cell is low, because partial photons in the incident light are absorbed by the front electrode and the N-type silicon layer. Thus, carriers generated by exciting of photons in the P-N junction are relatively few, and a photoelectric conversion efficiency of the solar cell is relatively low.

What is needed, therefore, is to provide a solar cell having a high photoelectric conversion efficiency, a solar cell system, and a method for making the same.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is a front view of an embodiment of a solar cell.

FIG. 2 is a structural schematic view of the solar cell of FIG. 1.

FIG. 3 is a front view of an embodiment of a solar cell system.

FIG. 4 is a structural schematic view of the solar cell system of FIG. 3.

FIG. 5 is a flow chart of an embodiment of a method for making the solar cell system.

FIG. 6 is a schematic view of the method of FIG. 5.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean at least one.

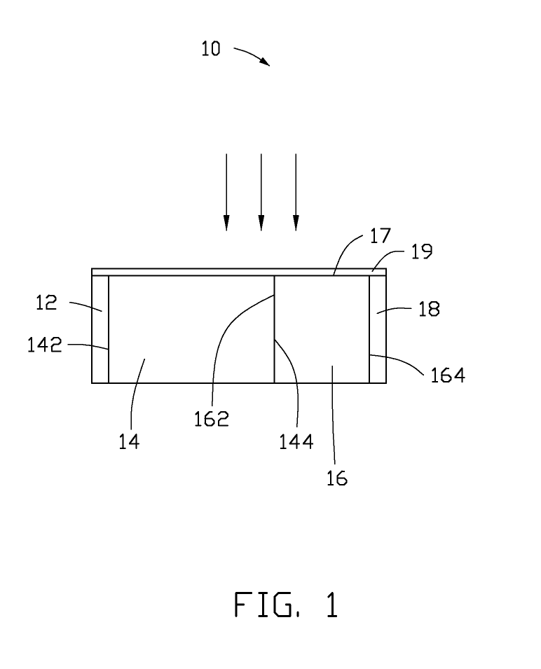

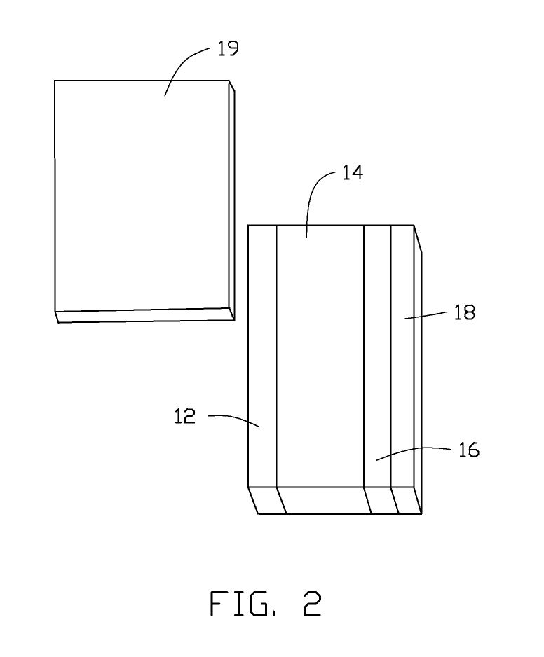

Referring to FIGS. 1 and 2, one embodiment of a solar cell 10 includes a first electrode layer 12, a P-type silicon layer 14, an N-type silicon layer 16, and a second electrode layer 18. The first electrode layer 12, the P-type silicon layer 14, the N-type silicon layer 16, and the second electrode layer 18 can be arranged in series, side by side, in that order, cooperatively forming a planar structure. The planar structure has a photoreceptive surface 17 across the planar structure of the first electrode layer 12, the P-type silicon layer 14, the N-type silicon layer 16, and the second electrode layer 18. The photoreceptive surface 17 is used to directly receive an incident light. The P-type silicon layer 14 has a first surface 142 and a second surface 144 opposite to the first surface 142. The N-type silicon layer 16 has a first surface 162 and a second surface 164 opposite to the first surface 162. The first electrode layer 12 is electrically connected and contacting with the first surface 142 of the P-type silicon layer 14. The second electrode layer 18 is electrically connected and contacting with the second surface 164 of the N-type silicon layer 16. The second surface 144 of the P-type silicon layer 14 and the first surface 162 of the N-type silicon layer 16 is electrically connected and contacting with each other to form a P-N junction.

The P-type silicon layer 14 has a first side surface connected with the first surface 142 and the second surface 144. The N-type silicon layer 16 has a first side surface connected with the first surface 162 and the second surface 164. The first side surfaces of the P-type silicon layer 14 and the N-type silicon layer 16 cooperatively form the photoreceptive surface 17. The P-N junction is formed near an interface between the P-type silicon layer 14 and the N-type silicon layer 16 and exposed from the photoreceptive surface 17.

The P-type silicon layer 14 is a laminar structure. A material of the P-type silicon layer 14 can be monocrystalline silicon, polycrystalline silicon, or other P-type semiconducting material. A thickness of the P-type silicon layer 14 along a direction from the first surface 142 to the second surface 144, can be in a range from about 200 micrometers (μm) to about 300 μm. An angle between the first side surface and the first surface 142 or the second surface 144 can be larger than 0 degrees and less than 180 degrees. In one embodiment, the angle is about 90 degrees, namely, the first side surface is substantially perpendicular to the first surface 142 and the second surface 144, and the P-type silicon layer 14 is a P-type monocrystalline silicon sheet having 200 μm in thickness.

The N-type silicon layer 16 is a laminar structure. The N-type silicon layer 16 can be formed by injecting superfluous N-type doping elements (e.g. phosphorus or arsenic) into a silicon sheet. A thickness of the N-type silicon layer 16, along a direction from the first surface 162 to the second surface 164, can be in a range from about 10 nanometers (nm) to about 1 μm. An angle between the second side surface and the first surface 142, or the second side surface and the second surface 144 can be larger than 0 degrees and less than 180 degrees. In one embodiment, the angle is about 90 degrees, namely, the first side surface is perpendicular to the first surface 162 and the second surface 164, and the thickness of the N-type silicon layer 16 is about 50 nm.

An inner electric field having a field direction from the N-type silicon layer to P-type silicon layer is formed, because surplus electrons in the N-type silicon layer 16 diffuse across the P-N junction and reach the P-type silicon layer 14. When a plurality of electron-hole pairs are generated in the P-N junction due to excitation of an incident light, the electrons and the holes are separated from each other under the inner electric field. Specifically, the electrons in the N-type silicon layer 16 move toward the second electrode layer 18, and are gathered by the second electrode layer 18. The holes in the P-type silicon layer 14 move toward the first electrode layer 12, and are gathered by the first electrode layer 12. Thus, a current is formed, thereby realizing a conversion from the light energy to the electrical energy.

In use, the incident light does not reach the P-N junction through the first electrode layer 12, namely, the first electrode layer 12 will not obstruct the incident light to reach the P-N junction. Thus, the first electrode layer 12 can be a continuous planar shaped structure coated on the entire first surface 142 of the P-type silicon layer 14, or a lattice shaped structure coated on the partial surface 142 of the P-type silicon layer 14. A material of the first electrode layer 12 is conductive material, such as metal, conducting polymer, indium tin oxide, and carbon nanotube structure. In one embodiment, the first electrode layer 12 is made of a metal material layer having a continuous planar shaped structure and coated on the entire first surface 142. The metal material can be aluminum, copper, or silver. A thickness of the first electrode layer 12 is not limited, and can be in a range from about 50 nm to about 300 nm. In one embodiment, the first electrode layer 12 is an aluminum sheet having a thickness of 200 nm.

Furthermore, the incident light does not reach the P-N junction through the second electrode layer 18. Thus, the second electrode layer 18 can be a continuous planar shaped structure coated on the entire second surface 164 of the N-type silicon layer 16, or a lattice shaped structure partially coated on the second surface 164. A material of the second electrode layer 18 can be conductive material, such as metal, conducting polymer, indium tin oxide, and carbon nanotube structure. In one embodiment, the second electrode layer 18 is made of a metal material layer having a continuous planar shaped structure and coated on the entire second surface 164. The metal material can be aluminum, copper, or silver. A thickness of the second electrode layer 18 is not limited, and can be in a range from about 50 nm to about 300 nm. In one embodiment, the second electrode layer 18 is an aluminum sheet having a thickness of 200 nm.

In addition, the material of the first electrode layer 12 and the second electrode layer 18 can be opaque to avoid leakage of the incident light passing through the first electrode layer 12 and the second electrode layer 18, and decreasing photoelectric conversion efficiency of the solar cell 10.

The incident light irradiates the photoreceptive surface 17 of the first side surfaces of the P-type silicon layer 14 and the N-type silicon layer 16. The second electrode layer 18 does not coat the photoreceptive surface 17, namely, the P-N junction is directly exposed from the photoreceptive surface 17. Thus, the photons in the incident light directly reach the P-N junction without passing through the second electrode layer 18 and the N-type silicon layer 16, and can be directly absorbed by the P-N junction. Accordingly, the second electrode layer 18 and the N-type silicon layer 16 cannot obstruct the incident light to reach the P-N junction, thereby increasing the light absorbing efficiency of the P-N junction. Correspondingly, the P-N junction can excite more electron-hole pairs under the irradiation of the incident light. In addition, the second electrode layer 18 can have any shape and cannot obstruct light. In one embodiment, the second electrode layer 18 having a planar shaped structure is coated on the entire fourth surface 164 of the N-type silicon layer 16. Thus, the second electrode layer 18 has a large area, thereby decreasing the diffusing distance of the carriers in the second electrode layer 18 and the interior loss of the carriers, and increasing the photoelectric conversion efficiency of the solar cell 10.

In addition, an angle between the photoreceptive surface 17 and the second surface 164 of the N-type silicon layer 16 can be in a range from about 0 degrees to about 180 degrees. In one embodiment, the angle is about 90 degrees.

Furthermore, an antireflection layer 19 can be disposed on the photoreceptive surface 17 to decrease reflection of the incident light and increase absorption of the incident light. The antireflection layer 19 can absorb little light. A material of the antireflection layer 19 can be silicon nitride (Si₃N₄) or silicon dioxide (SiO₂). A thickness of the antireflection layer 19 can be less than 150 nm. In one embodiment, the antireflection layer 19 is the silicon nitride layer having the thickness of 900 angstrom (Å).

A thickness of the solar cell 10 is a distance between the photoreceptive surface 17 and a surface opposite to the photoreceptive surface 17. When the photoreceptive surface 17 is substantially perpendicular to the second surface 164, the thickness of the solar cell 10 is a width of the P-type silicon layer 14, N-type silicon layer 16, a first electrode layer 12, and a second electrode layer 18 along a direction perpendicular to the photoreceptive surface 17. The thickness of the solar cell 10 is not limited, and can be set by the light transmittance of the P-type silicon layer 14 and the N-type silicon layer 16. Specifically, if the light transmittance of the P-type silicon layer 14 and the N-type silicon layer 16 is large, the thickness of the solar cell 10 can be appropriately increased to decrease the light transmittance. Consequently, the solar cell 10 can efficiently absorb the light. In one embodiment, the thickness of the solar cell 10 is in a range from about 50 μm to about 300 μm.

The first electrode layer 12 and the second electrode 18 will not obstruct the light to irradiate the P-N junction. Thus, the shape and structure of the first electrode layer 12 and the second electrode layer 18 can be arbitrarily set, thereby decreasing the complexity of fabricating the solar cell 10.

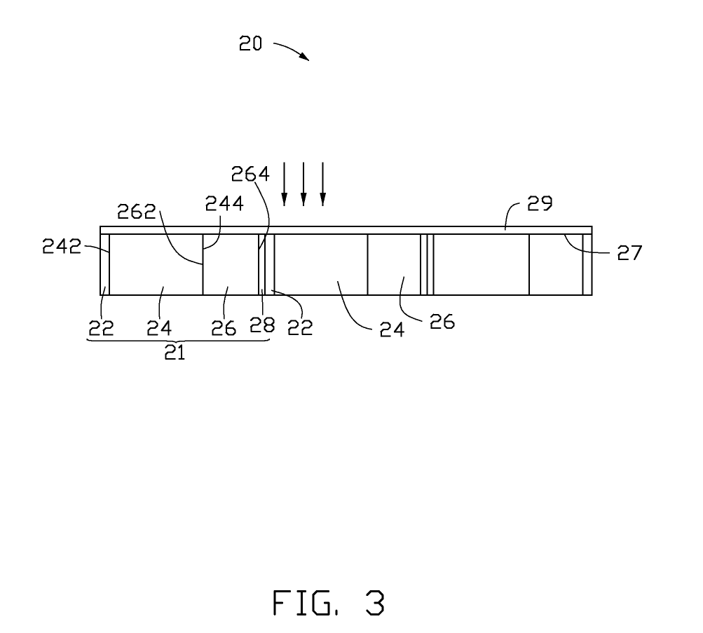

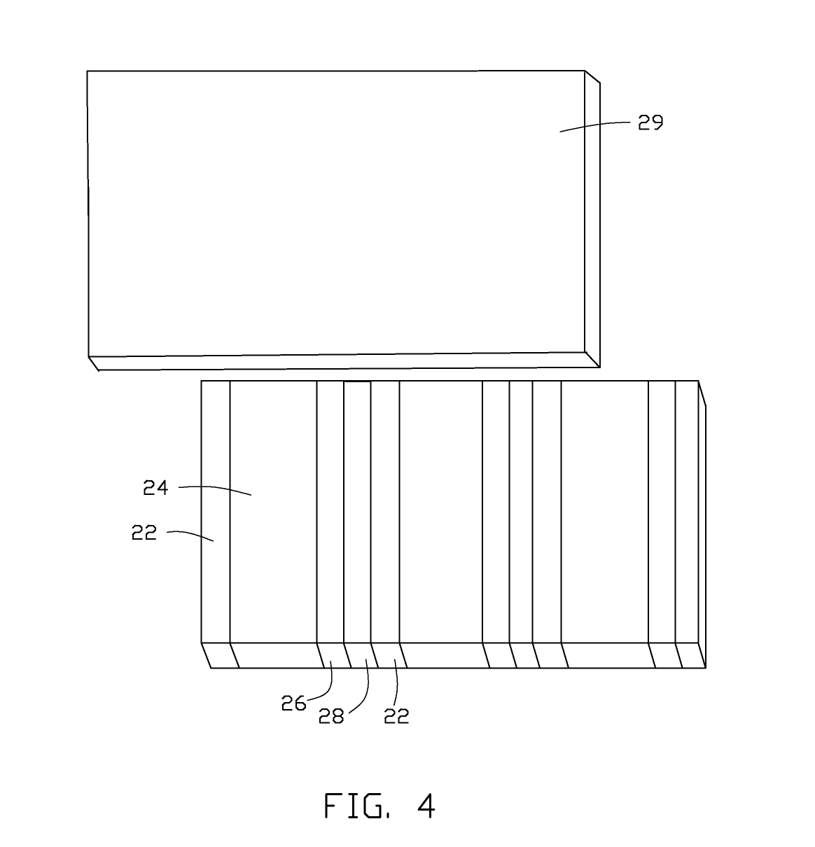

Referring to FIGS. 3 and 4, one embodiment of a solar cell system 20 includes a plurality of the aforementioned solar cells 10 connected in series. The plurality of solar cells 10 are arranged side by side and contacting each other. The second electrode layer 18 of each solar cell 10 contacts the first electrode layer 12 of the adjacent solar cell 10. The photoreceptive surfaces 17 of the plurality of solar cells 10 cooperatively form a photoreceptive surface 27 of the solar cell system 20. The photoreceptive surface 27 directly receives incident light.

The second electrode layer 18 of each solar cell 10 and the first electrode layer 12 of the adjacent solar cell 10 can be bonded with each other or adhered to each other by a conductive adhesive. The material of the second electrode layer 18 of each solar cell 10 and the first electrode layer 12 of the adjacent solar cell 10 can be the same or different. If the material of the second electrode layer 18 of each solar cell 10 and the first electrode layer 12 of the adjacent solar cell 10 are the same, the second electrode layer 18 of each solar cell 10 and the first electrode layer 12 of the adjacent solar cell 10 can be bonded with each other or substituted by a single electrode layer. In one embodiment, the plurality of solar cells 10 can be pressed together to form an integral structure.

In one embodiment, the first electrode layer 12 of each solar cell 10 is a metal material layer coated on the entire first surface 142 of the P-type silicon layer 14. The second electrode layer 18 of each solar cell 10 is a metal material layer coated on the entire second surface 164 of the N-type silicon layer 16.

In the solar cell system 20, the occupancy area of the electrode layers in the photoreceptive surface 27 can be controlled by a thickness of the first electrode layer 12 and the second electrode layer 18 of each solar cell 10, thereby increasing the effective area for light to irradiate the photoreceptive surface 27. Specifically, a total thickness of the first electrode layer 12 of each solar cell 10 and the second electrode layer 18 of the adjacent solar cell 10 can be in a range from about 100 nm to about 400 nm. In one embodiment, the total thickness of the first electrode layer 12 of each solar cell 10 and the second electrode layer 18 of the adjacent solar cell 10 along a direction from the first surface 142 to the second surface 144 is about 300 nm.

Furthermore, an antireflection layer 29 is disposed on the photoreceptive surface 27 of the solar cell system 20, thereby decreasing light reflecting from the photoreceptive surface 27 and increasing light absorption of the P-N junction. The antireflection layer 29 can absorb little light. A material of the antireflection layer 29 can be silicon nitride or silicon dioxide. A thickness of the antireflection layer 29 can be less than about 150 nm. In one embodiment, the antireflection layer 29 is silicon nitride layer having the thickness of about 900 Å.

The number of the solar cells 10 in the solar cell system 20 is not limited and can be set according to an output voltage of the solar cell system 20. In one embodiment, the solar cell system 20 includes one hundred solar cells 10. An operating voltage of the solar cell system 20 is an integral multiple of the operating voltage of one solar cell 10.

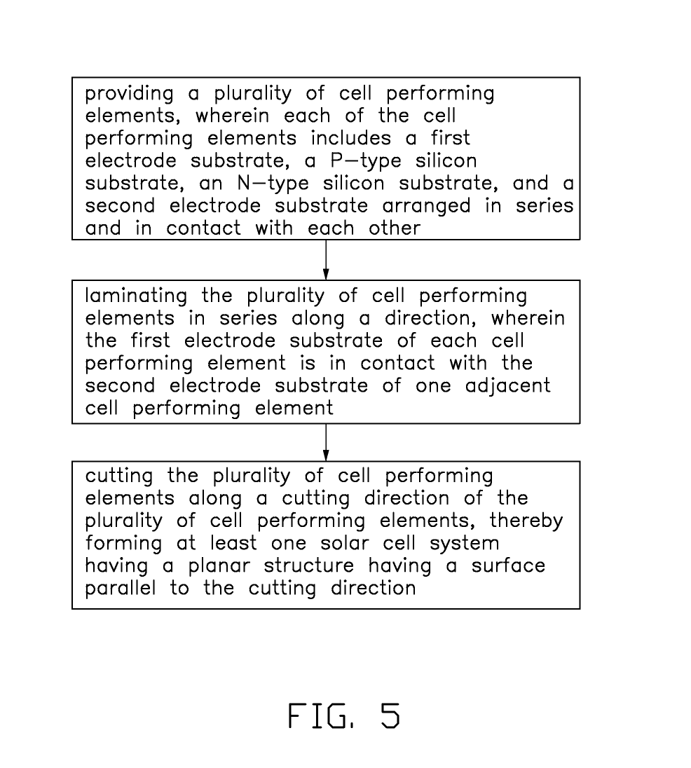

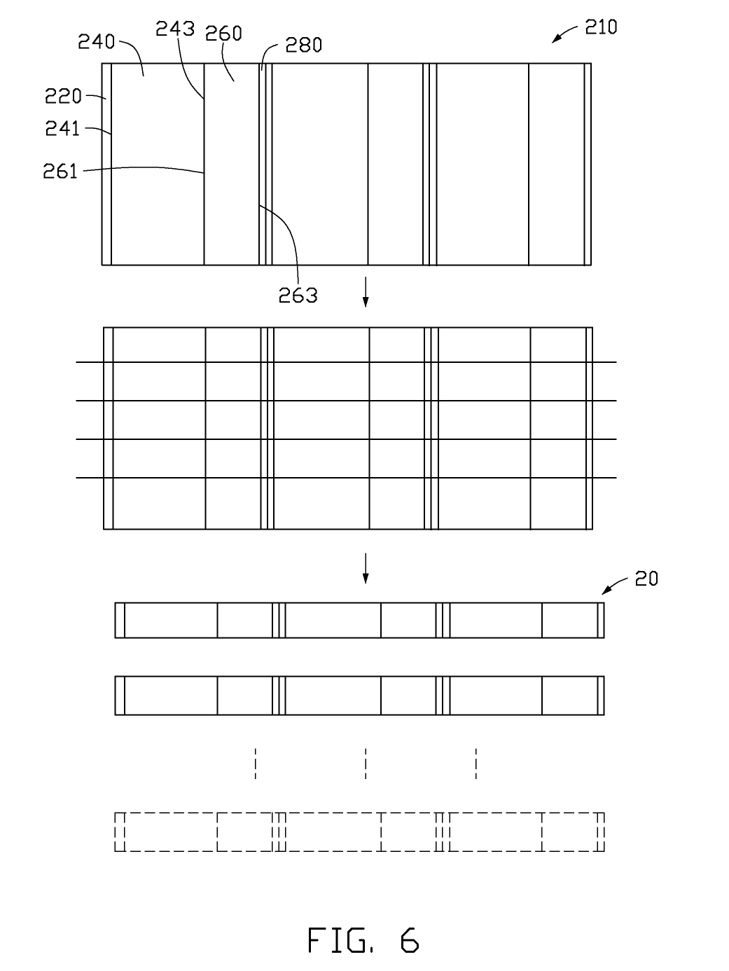

Referring to FIGS. 5 and 6, one embodiment of a method for making the solar cell system 20 includes the following steps:

S1, providing a plurality of cell performing elements 210, wherein each of the cell performing elements 210 includes a first electrode substrate 220, a P-type silicon substrate 240, an N-type silicon substrate 260, and a second electrode substrate 280 arranged in series and in contact with each other;

S2, laminating the plurality of cell performing elements 210 in series along a direction, wherein the first electrode substrate 220 of each cell performing element 210 is in contact with the second electrode substrate 240 of one adjacent cell performing element 210;

S3, cutting the plurality of cell performing elements 210 along a cutting direction of the plurality of cell performing elements 210, thereby forming at least one solar cell system having a planar structure having a surface parallel to the cutting direction.

In step S1, the P-type silicon substrate 240 has a first surface 241 and a second surface 243 opposite to the first surface 241. The N-type silicon substrate 260 has a first surface 261 and an second surface 263 opposite to the first surface 261. The first electrode substrate 220 is disposed on the first surface 241 of the P-type silicon substrate 240. The second electrode substrate 280 is disposed on the second surface 263 of the N-type silicon substrate 260. The second surface 243 of the P-type silicon substrate 240 contacts the first surface 261 of the N-type silicon substrate 260, thereby forming a P-N junction. The P-type silicon substrate 240 is a P-type silicon sheet. A material of the P-type silicon sheet can be monocrystalline silicon, polycrystalline silicon, or other P-type semiconducting material. In one embodiment, the P-type silicon substrate 240 is a P-type monocrystalline silicon sheet. A thickness of the P-type monocrystalline silicon sheet can be in a range from about 200 μm to about 300 μm. A shape and area of the P-type silicon substrate 240 are not limited and can be set as needed. The N-type silicon substrate 260 can be formed by injecting surplus N-type doping elements (e.g. phosphorus or arsenic) into a silicon sheet. A thickness of the N-type silicon substrate 260 can be in a range from about 10 nm to about 1 μm.

A material of the first electrode substrate 220 and a material of the second electrode substrate 280 can be the same or different. In one embodiment, the first electrode substrate 220 and the second electrode substrate 280 can be composed of a metal material layer having a continuous planar structure. The metal material layer can be made of aluminum, copper, or silver. The first electrode substrate 220 and the second electrode substrate 280 can be respectively adhered on the P-type silicon substrate 240 and the N-type silicon substrate 260 by a conductive adhesive, or respectively formed on the P-type silicon substrate 240 and the N-type silicon substrate 260 by a process of vacuum evaporating or magnetron sputtering.

In step S2, the plurality of cell performing elements 210 can be adhered to each other by a conductive adhesive. In addition, if a material of the first electrode substrate 220 of each cell performing element 210 is the same as a material of the second electrode substrate 280 of the adjacent cell performing element 210, the plurality of cell performing elements 210 can be pressed together by a pressing machine, thereby bonding together the electrode substrates of the two adjacent cell performing elements 210. A force applied on the plurality of cell performing elements 210 by the pressing machine is not limited and can be applied to bond the first electrode substrate 220 and the second electrode substrate 280 in the adjacent cell performing elements 210 into an integrative structure.

In S3, the cutting method is not limited. The plurality of cell performing elements 210 in contact with each other are cut along the cutting direction passing through the first surface 241 and the second surface 243 of the P-type silicon substrate 240, and the first surface 261 and the second surface 263 of the N-type silicon substrate 260, thereby forming at least one solar cell system 20 having a planar structure having a photoreceptive surface 27. The photoreceptive surface 27 of the planar structure is parallel to the cutting direction. In one embodiment, the cutting direction is perpendicular to the first surface 241 and the second surface 243 of the P-type silicon substrate 240, and the first surface 261 and the second surface 263 of the N-type silicon substrate 260. The photoreceptive surface 27 is directly exposed.

Furthermore, after step S3, an antireflection layer 29 can be formed on the photoreceptive surface 27 by a process of vacuum evaporating or magnetron sputtering.

Depending on the embodiment, certain steps of methods described may be removed, others may be added, and the sequence of steps may be altered. It is also to be understood, that the description and the claims drawn to a method may include some indication in reference to certain steps. However, the indication used is only to be viewed for identification purposes and not as a suggestion as to an order for the steps.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A solar cell, comprising a first electrode layer, a P-type silicon layer, an N-type silicon layer, and a second electrode layer, wherein the first electrode layer, the P-type silicon layer, the N-type silicon layer, and the second electrode layer are arranged in series side by side along a straight line and in contact with each other, thereby cooperatively forming a planar structure having a photoreceptive surface substantially parallel to the straight line to directly receive incident light, and a P-N junction is formed near an interface between the P-type silicon layer and the N-type silicon layer.

2. The solar cell as claimed in claim 1, wherein the P-type silicon layer has a first surface and a second surface opposite to the first surface, the N-type silicon layer has a first surface and a second surface opposite to the first surface, the first electrode layer is electrically contacted with the first surface of the P-type silicon layer, the second electrode layer is electrically contacted with the second surface of the N-type silicon layer, the P-type silicon layer has a first side surface connected with the first surface and the second surface of the P-type silicon layer, the N-type silicon layer has a second side surface connected with the first surface and the second surface the N-type silicon layer, and the first side surface and the second side surface cooperatively form the photoreceptive surface.

3. The solar cell as claimed in claim 2, wherein the first electrode layer has a continuous planar shaped structure coated on the entire first surface of the P-type silicon layer, the second electrode layer has a continuous planar shaped structure coated on the entire second surface of the N-type silicon layer.

4. The solar cell as claimed in claim 3, wherein the first electrode layer and the second electrode layer are opaque metal material layer.

5. The solar cell as claimed in claim 2, wherein the incident light irradiates the photoreceptive surface along a direction substantially perpendicular to the photoreceptive surface.

6. The solar cell as claimed in claim 1, wherein an antireflection layer having a thickness of about 150 nm is coated on the photoreceptive surface.

7. The solar cell as claimed in claim 6, wherein a material of the antireflection layer is silicon nitride or silicon dioxide.

8. The solar cell as claimed in claim 1, wherein the P-N junction is exposed out from the photoreceptive surface.

9. The solar cell as claimed in claim 1, wherein a thickness of the solar cell between the photoreceptive surface and a surface opposite to the photoreceptive surface of the solar cell is in a range from about 50 μm to about 300 μm.

10. A solar cell system, comprising a plurality of solar cells connected in series, each of the plurality of solar cells comprising a first electrode layer, a P-type silicon layer, an N-type silicon layer, and a second electrode layer, wherein the first electrode layer, the P-type silicon layer, the N-type silicon layer, and the second electrode layer are arranged in series and side by side along a straight line and in contact with each other, thereby cooperatively forming a planar structure having a photoreceptive surface substantially parallel to the straight line to directly receive an incident light, a P-N junction is formed near an interface between the P-type silicon layer and the N-type silicon layer.

11. The solar cell system as claimed in claim 10, wherein the first electrode layer of each of the plurality of solar cells is in contact with the second electrode layer of one adjacent solar cell of the plurality of solar cells.

12. The solar cell system as claimed in claim 11, wherein the P-N junction of each of the plurality of solar cells is exposed out from the photoreceptive surface.

13. A method for making a solar cell system, comprising:
providing a plurality of cell performing elements, wherein each of the plurality of cell performing elements comprises a first electrode substrate, a P-type silicon substrate, an N-type silicon substrate, and a second electrode substrate arranged in series and in contact with each other;
laminating the plurality of cell performing elements in series, wherein the first electrode substrate of each of the plurality of cell performing elements is in contact with the second electrode substrate of one adjacent cell performing element of the plurality of cell performing elements;
cutting the plurality of cell performing elements along a cutting direction, thereby forming at least one solar cell system having a planar structure having a photoreceptive surface substantially parallel to the cutting direction.

14. The solar cell system as claimed in claim 13, wherein the plurality of cell performing elements are adhered to each other by a conductive adhesive.

15. The solar cell system as claimed in claim 13, wherein the first electrode substrate and the second electrode substrate are composed of metal material layer.

16. The solar cell system as claimed in claim 15, wherein the plurality of cell performing elements are pressed together, thereby bonding the first electrode substrate of each of the plurality of cell performing elements with the second electrode substrate of one adjacent cell performing element of the plurality of cell performing elements.

17. The solar cell system as claimed in claim 13, wherein the cutting direction passes through the first electrode substrate, the P-type silicon substrate, the N-type silicon substrate, and the second electrode substrate.

18. The solar cell system as claimed in claim 13, wherein an antireflection layer is formed on the photoreceptive surface by a process of vacuum evaporating or magnetron sputtering.
